(19) United States
(12) Patent Application Publication
(10) Pub. No.: US 2013/0313650 A1
(43) Pub. Date: Nov. 28, 2013

(54) TID HARDENED MOS TRANSISTORS AND FABRICATION PROCESS

(71) Applicant: Microsemi SoC Corp., San Jose, CA (US)

(72) Inventors: Ben Schmid, Austin, TX (US); Fethi Dhaoui, Mountain Horse, CA (US); John McCollum, Saratoga, CA (US)

(73) Assignee: Microsemi SoC Corp., San Jose, CA (US)

(21) Appl. No.: 13/895,554

(22) Filed: May 16, 2013

Related U.S. Application Data
(60) Provisional application No. 61/651,689, filed on May 25, 2012.

(51) Int. Cl. H01L 29/06

(52) U.S. Cl. CPC H01L 29/0642
USPC 257/368

(57) ABSTRACT

A radiation-hardened transistor is formed in a p-type body. An active region is disposed within the p-type body and has a perimeter defined by a shallow-trench isolation region filled with a dielectric material. Spaced-apart source and drain regions are disposed in the active region, forming a channel therebetween. A polysilicon gate is disposed above, aligned with, and insulated from the channel region. A p-type isolation ring is disposed in the p-type body separating outer edges of at least one of the source and drain regions from the perimeter of the active region.

### CROSS-REFERENCE TO RELATED APPLICATIONS

The present application claims the priority benefit of U.S. provisional application No. 61/651,689 filed May 25, 2012 and entitled “TID Hardened MOS Transistors and Fabrication Process,” the disclosure of which is incorporated herein by reference.

### BACKGROUND

1. Field of the Invention

The present invention relates to semiconductor technology, and specifically to MOS technology. More particularly, the present invention relates to radiation hardened MOS transistors and to methods for fabricating such transistors.

2. The Prior Art

The present invention is intended to solve the problem of transistor off-state leakage in n-channel MOS (NMOS) high-voltage (HV) transistors due to ionizing radiation. Ionizing radiation over time deposits positive charge in the insulating materials surrounding the transistor, causing NMOS devices to exhibit large parasitic drain-to-source leakages along the now inverted transistor sidewalls. These large leakage currents limit the usable lifetime of NMOS transistors in radiation environments. Due to the lower body doping of HV transistors, these devices are especially vulnerable to this failure mechanism.

Total Ionizing Dose (TID) is a long-term degradation of electronics due to the cumulative energy deposited in a material. Typical effects include parametric failures, or degradations in device parameters such as increased leakage current, threshold voltage shifts, or functional failures. Major sources of TID exposure in the space environment include trapped electrons, trapped protons, and solar protons, as well as trapped charge in dielectrics caused by X-Rays and Gamma Rays and high energy ions.

There are several transistor degradation modes caused as a result of ionization dose. One is a shift in threshold voltage Vₜ. The Vₜ of NMOS and PMOS devices shift in a negative direction due to hole trapping in the gate oxide. Another is sidewall leakage.

The Vₜ of parasitic isolation sidewall transistors also shifts in a negative direction. For NMOS transistors, as Vₜ becomes more negative, sidewall leakage increases exponentially as the parasitic transistor starts to turn on at a lower threshold voltage. This is the primary lifetime limitation for standard medium voltage (MV) and high-voltage (HV) NMOS devices. Shallow-trench isolation (STI) accumulates positive charge during irradiation. The positive charge turns on parasitic sidewall transistors at the STI edges, forming an uncontrolled conducting path from drain to source.

FIGS. 1A through 1C illustrate the effects of TID on a typical linear NMOS STI isolated transistor. FIG. 1A is an isometric view of the structure, FIG. 1B is a cross-sectional view of the left-most portion of the structure taken through the drain, and FIG. 1C is a side view of the edge of the structure at the inner boundary of the STI isolation trench. Positive charge built up in the STI oxide (shown as multiple “+” signs in FIGS. 1A and 1B) lowers the threshold of the transistor, causing leakage current to flow from the drain to source along the edge of the structure through a parasitic transistor that exists at the gate edge proximate to the STI boundary as shown by arrow 10 in FIGS. 1A and 1C.

Existing prior-art layout solutions to this problem include transistors formed using annular gate geometries in which there are no isolation sidewalls connecting the drain and source nodes, because the gate completely encircles the drain of the transistor.

FIGS. 2A and 2B are top and cross sectional views of an annular-gate transistor and illustrate an example layout of an existing annular-gate solution to the ionizing radiation problem for fabricating HV NMOS devices. The annular-gate transistor is fabricated within a boundary defined by a shallow trench isolation (STI) structure comprising a shallow trench filled with an insulating material such as a deposited silicon dioxide. An annular polysilicon gate is formed and defined in the center of the transistor region defined by the STI structure. An annular source region and a square-shaped drain region are then implanted by a self-aligned-gate process using the annular gate as an implant mask as is known in the art. The source comprises the region outside of the gate abutting the inner perimeter of the STI structure and the drain is formed through an aperture in the center of the gate.

As may be seen from an examination of FIGS. 2A and 2B, there is no drain edge at the inner STI periphery, since the annular source completely occupies the edge of the transistor structure. While this prevents the existence of a parasitic transistor at the gate edge at the STI region, since there is no gate edge at this location in the transistor, this solution to the problem is not entirely satisfactory.

It is difficult to scale width and length for transistor design in such structures. For example, SPICE models cannot easily be used to determine effective widths and lengths of such devices. Curved and circular structures are not provided for in conventional simulation software to model transistors. In addition, as geometries shrink, the right-angle edges of the structures in the annular gate transistor become disallowed in design rules, creating a lower limit on the size of such transistors. For example below 65 nm, design rules prohibit 90° or even 45° angles on polysilicon over diffusion.

Another prior art solution to the problem when using lateral transistors with STI isolation has been to add an additional p-type implant to the diffusion sidewall. This implant is performed after trench etch and before trench fill. This solution delays the onset of parasitic leakage, but does not eliminate it. In addition, the additional sidewall implant degrades junction breakdown, which is problematic in HV transistors.

### BRIEF DESCRIPTION

According to a first aspect of the present invention, a lateral n-p junction is created in the transistor to isolate the device channel from the sidewall of the STI isolation structure on both the source and drain regions of the transistor. Additional p-type implants may be added in this isolation ring to increase the parasitic Vₜ and improve TID immunity. The doping profile can be engineered so as not to degrade junction breakdown. In this embodiment of the invention, the drain of the transistor is isolated from STI by a lateral junction

According to another aspect of the present invention, a lateral n-p junction is created in the transistor to isolate the device channel from the sidewall of the STI isolation structure on only the drain region of the transistor.

According to another aspect of the present invention, additional P-type implants may be employed to increase TID immunity. The p-type implant may be separated from the edge of the N-type drain to preserve drain-body junction breakdown performance.

### BRIEF DESCRIPTION OF THE DRAWING FIGURES

FIGS. 1A 1B, and 1C are diagrams of an example layout of prior-art STI HV NMOS devices, illustrating the problems addressed by the present invention.

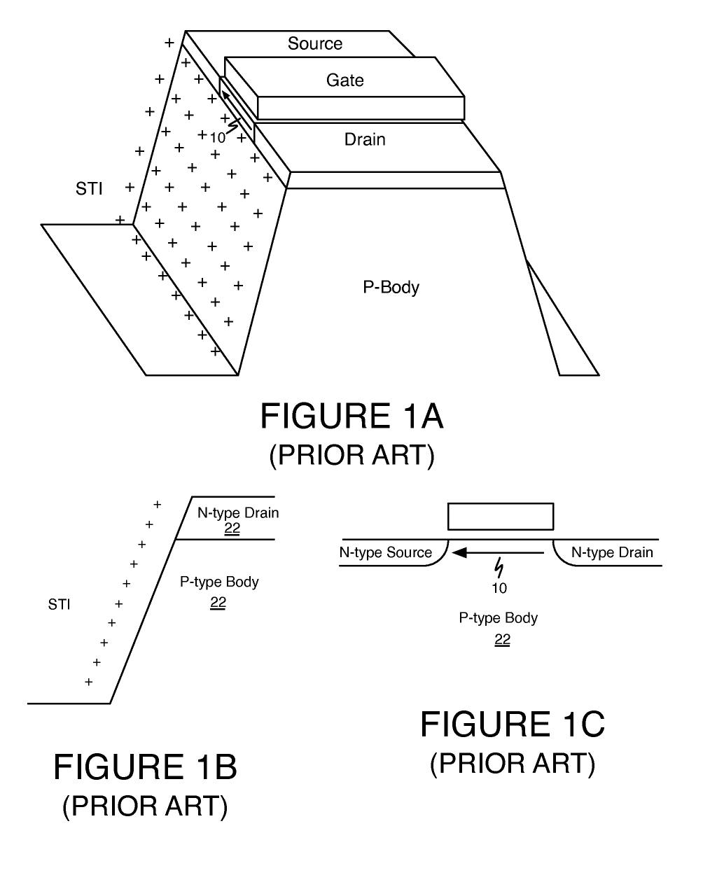

FIGS. 2A and 2B are diagrams of an example layout of an existing prior art annular gate transistor solution for constructing HV NMOS devices.

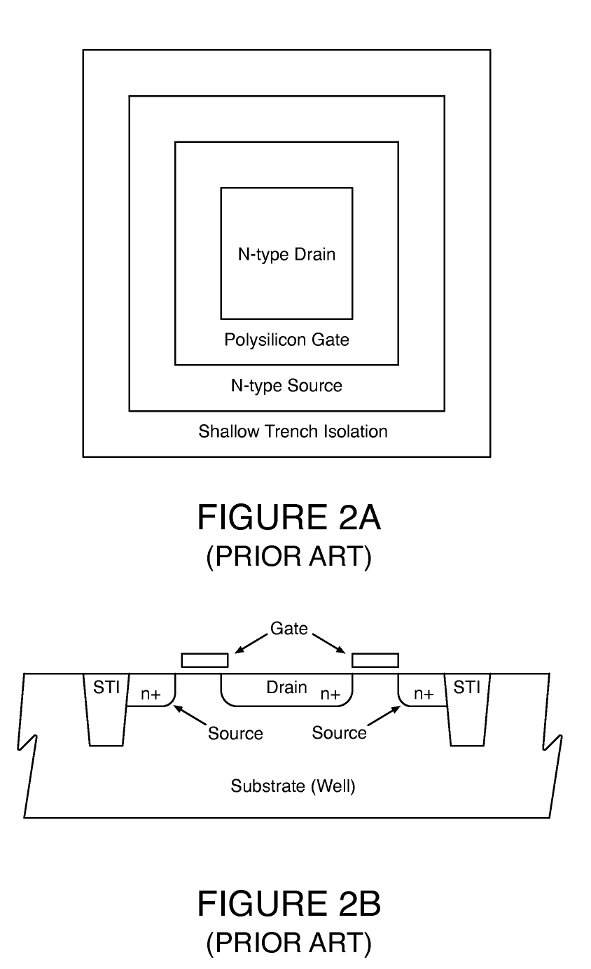

FIGS. 3A, 3B, and 3C are diagrams of an example layout of an STI isolated linear HV NMOS device according to one illustrative embodiment of the present invention.

FIGS. 4A, 4B, and 4C are diagrams of an example layout of an STI isolated linear HV NMOS device according to another illustrative embodiment of the present invention.

FIGS. 5A, 5B, and 5C are diagrams of an example layout of an STI isolated linear HV NMOS device according to another illustrative embodiment of the present invention.

FIGS. 6A, 6B, and 6C are diagrams of an example layout of an STI isolated linear HV NMOS device according to another illustrative embodiment of the present invention.

FIGS. 7A and 7B are diagrams of an example layout of an STI isolated linear HV NMOS device according to another illustrative embodiment of the present invention.

### DETAILED DESCRIPTION

Persons of ordinary skill in the art will realize that the following description of the present invention is illustrative only and not in any way limiting. Other embodiments of the invention will readily suggest themselves to such skilled persons.

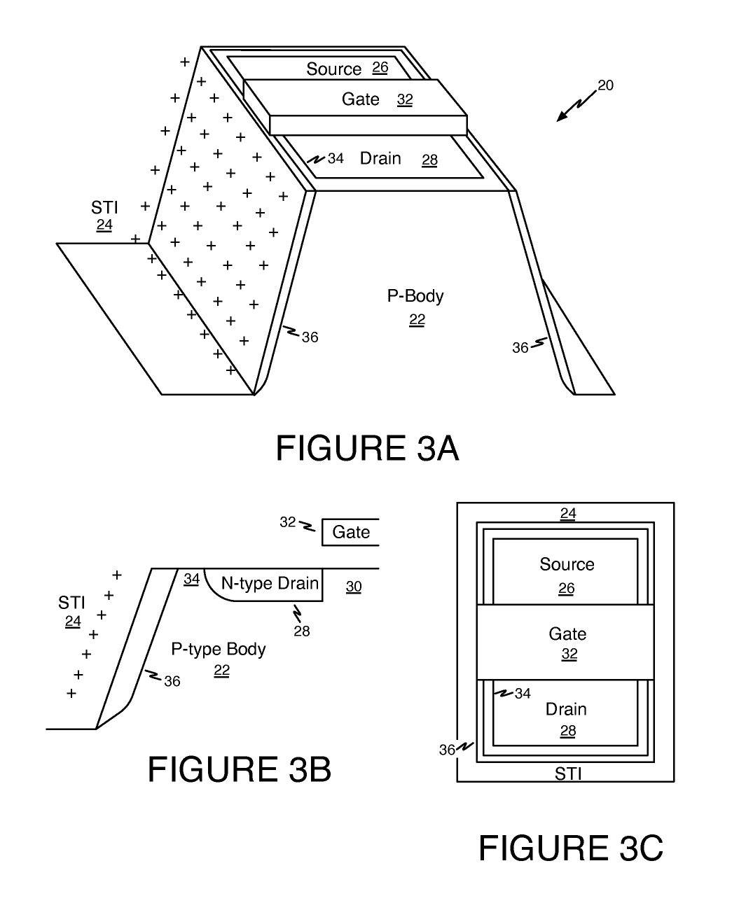

Referring now to FIGS. 3A, 3B, and 3C, diagrams depict an illustrative embodiment of the present invention. According to this aspect of the present invention, the source and drain nodes of the NMOS transistor are electrically isolated from the trench sidewall by a lateral diode. This diode is junction engineered to provide isolation after exposure to ionizing radiation while maintaining the full junction breakdown performance of the original radiation-sensitive layout.

FIG. 3A is a three-dimensional drawing of the structure of a transistor 20 fabricated according to one aspect of the present invention. FIG. 3B is a cross-sectional view of the drain side of transistor 20 taken in a direction parallel to the channel. FIG. 3C is a top view of the transistor.

Transistor 20 is formed in p-type body 22, which may be a high-voltage triple well, including a body p-well in a deep-n-well in a p-substrate. Typical doping levels for such a body p-well are about 1×10¹⁶ atoms/cm³. Transistor 20 is isolated by STI region 24 that surrounds the transistor. Source 26 and drain 28 define a channel region 30 disposed under a polysilicon gate 32. A typical doping level for sources and drains is from about 1×10¹⁹ atoms/cm³ to about 1×10¹⁹ atoms/cm³. The depth of a “deep-n-well” ranges from about 1 um to about 1.5 um in a process where a p-type body well junction depth ranges from 0.8 um to 1.5 um and an n-type well junction depth is from 0.8 um to 1.5 um.

In this embodiment of the present invention, the source 26 and drain 28 of the NMOS transistor 20 are electrically isolated from the trench sidewall by a lateral diode. This may be thought of as effectively replacing the parasitic sidewall transistors which exist in parallel with the channel of the device with a series of parasitic transistors with progressively higher threshold voltages (VT). The leakage is determined by the highest VT device, which can potentially withstand many times higher radiation doses before the onset of undesired conduction. The lateral diode space thereby allows these higher Vt dopings without sacrificing the breakdown voltage.

This lateral diode is formed by pulling the n-type source/drain implants back from the diffusion edge, leaving a region 34 of the p-type well or substrate doping. The perimeter of the diffusion is then implanted with additional p-type implant 36 to increase the parasitic threshold voltage and prevent punch-through to the inverted sidewall. P-type implant 36 is not shown at the front of the three-dimensional drawing of FIG. 3A in order to show the p-type body 22, although it is present there as shown in the top view of FIG. 3C. In a typical embodiment, the p-type implant can be at a level of about 1E16 atoms/cm³. In this device, the channel still exists under the gate, but it is disconnected from the transistor 20.

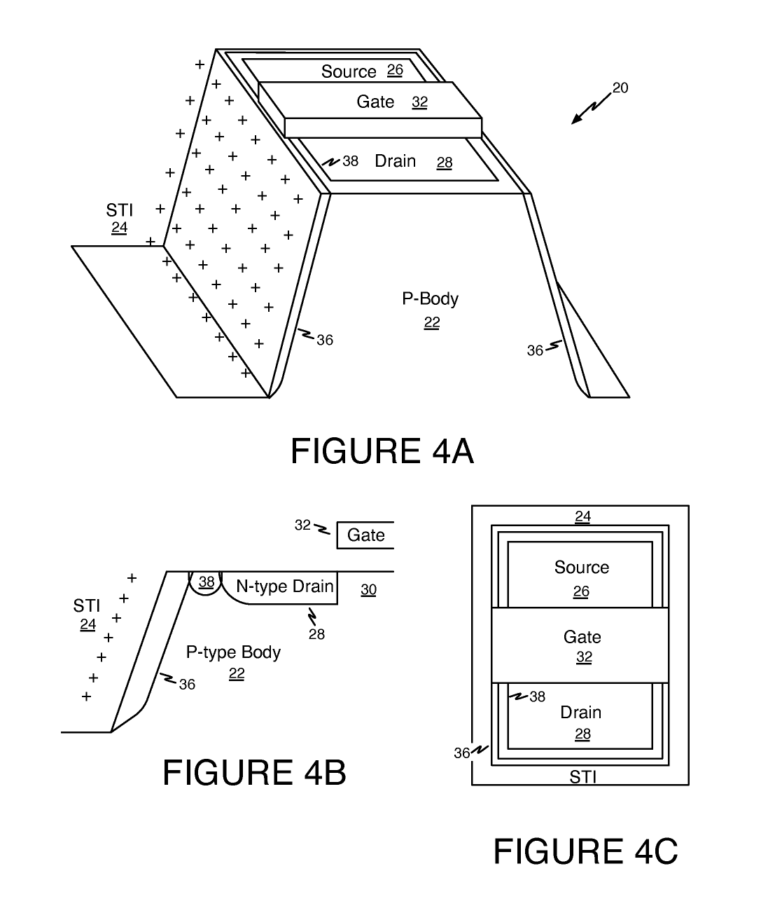

Referring now to FIGS. 4A through 4C, another embodiment of the present invention is shown. FIG. 4A is a three-dimensional drawing of the structure of a transistor 20 fabricated according to this aspect of the present invention. FIG. 4B is a cross-sectional view of the drain side of transistor 20 taken in a direction parallel to the channel. FIG. 4C is a top view of the transistor 20.

The embodiment shown in FIGS. 4A through 4C is a variant of the embodiment described with reference to FIGS. 3A through 3C. Instead of leaving a region 34 of the p-type well or substrate doping between the n-type source/drain implants and the diffusion edge, a lightly doped n-type region 38 is formed in that area. Region 38 is lightly doped n-type region, but is higher in doping than the P-type body 22. In a typical embodiment, the n-type implant can be at a level of about 3×10¹⁶ atoms/cm³. Because of the light doping, the BV will be high and can overlap the source/drain implants and the p-type implant 36, making the alignment non critical.

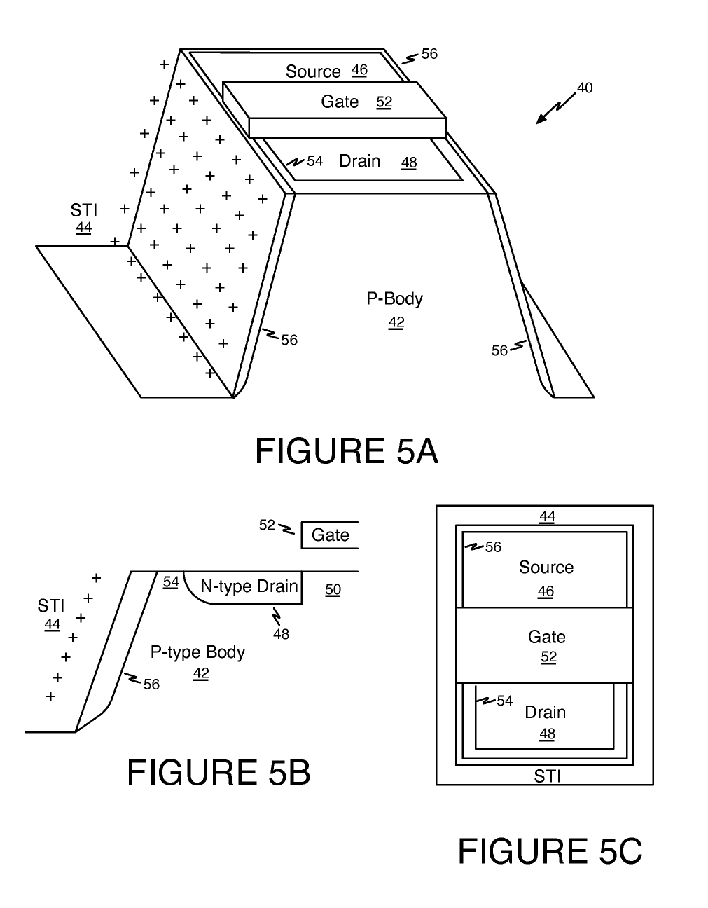

Referring now to FIGS. 5A through 5C, another embodiment of the present invention is shown. FIG. 5A is a three-dimensional drawing of the structure of a transistor 40 fabricated according to this aspect of the present invention. FIG. 5B is a cross-sectional view of the drain side of transistor 40 taken in a direction parallel to the channel. FIG. 5C is a top view of the transistor 40.

Like transistor 20 of the previously-described embodiment, transistor 40 is formed in p-type body 42, which may be a high-voltage triple well, including a body p-well in a deep-n-well in a p-substrate. Transistor 40 is isolated by STI region 44 that surrounds the transistor. Source 46 and drain 48 define a channel region 50 disposed under a polysilicon gate 52. A typical doping level for sources and drains is from about 1×10¹⁹ atoms/cm³ to about 1×10¹⁹ atoms/cm³.

In the embodiment of the present invention shown in FIGS. 5A, 5B, and 5C, only the drain 48 of the NMOS transistor 40 is electrically isolated from the trench sidewall by a lateral diode. This lateral diode is formed by pulling the n-type drain implant back from the diffusion edge, leaving a region 54 of the p-type well or substrate doping. The perimeter of the diffusion is then implanted with additional p-type implant 56 to increase the parasitic threshold voltage and prevent punch-through to the inverted sidewall. P-type implant 56 is not shown at the front of the three-dimensional drawing of FIG. 5A in order to show the p-type body 42, although it is present there as shown in the top view of FIG. 5C. In a typical embodiment, the p-type implant can be at a level of about 1E16 atoms/cm³.

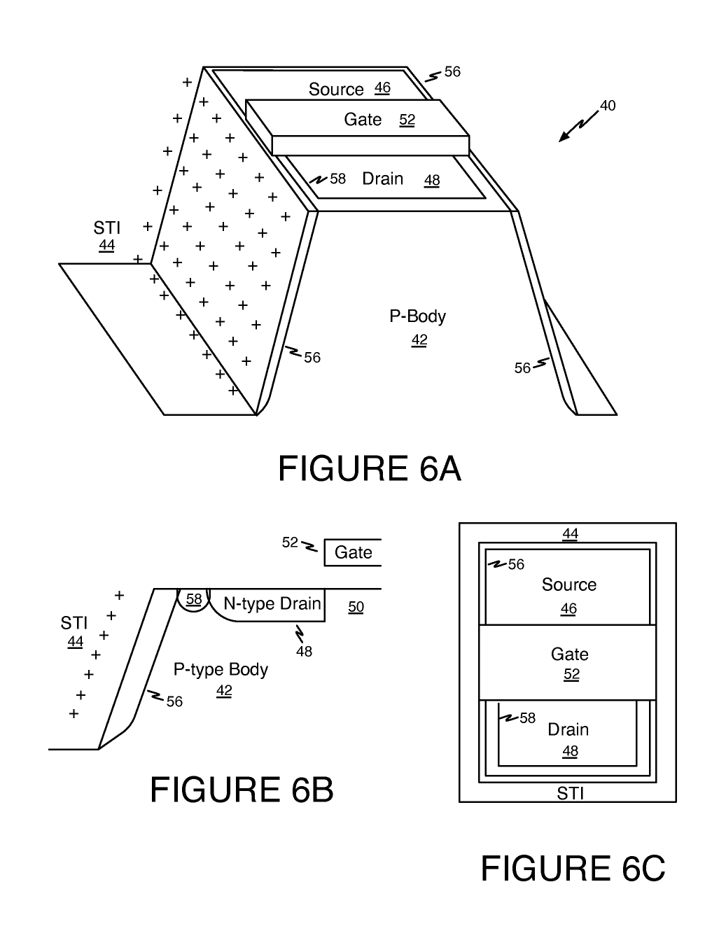

Referring now to FIGS. 6A through 6C, another embodiment of the present invention is shown. FIG. 6A is a three-dimensional drawing of the structure of a transistor 20 fabricated according to this aspect of the present invention. FIG. 6B is a cross-sectional view of the drain side of transistor 20 taken in a direction parallel to the channel. FIG. 6C is a top view of the transistor 20.

The embodiment shown in FIGS. 6A through 6C is a variant of the embodiment described with reference to FIGS. 5A through 5C. Instead of leaving a region 54 of the p-type well or substrate doping between the n-type source/drain implants and the diffusion edge, a lightly doped n-type region 58 is formed in that area. Region 58 is lightly doped n-type region, but is higher in doping than the P-type body 42. In a typical embodiment, the n-type implant can be at a level of about 3×10¹⁶ atoms/cm³. Because of the light doping, the BV will be high and can overlap the source/drain implants and the p-type implant 56, making the alignment non critical.

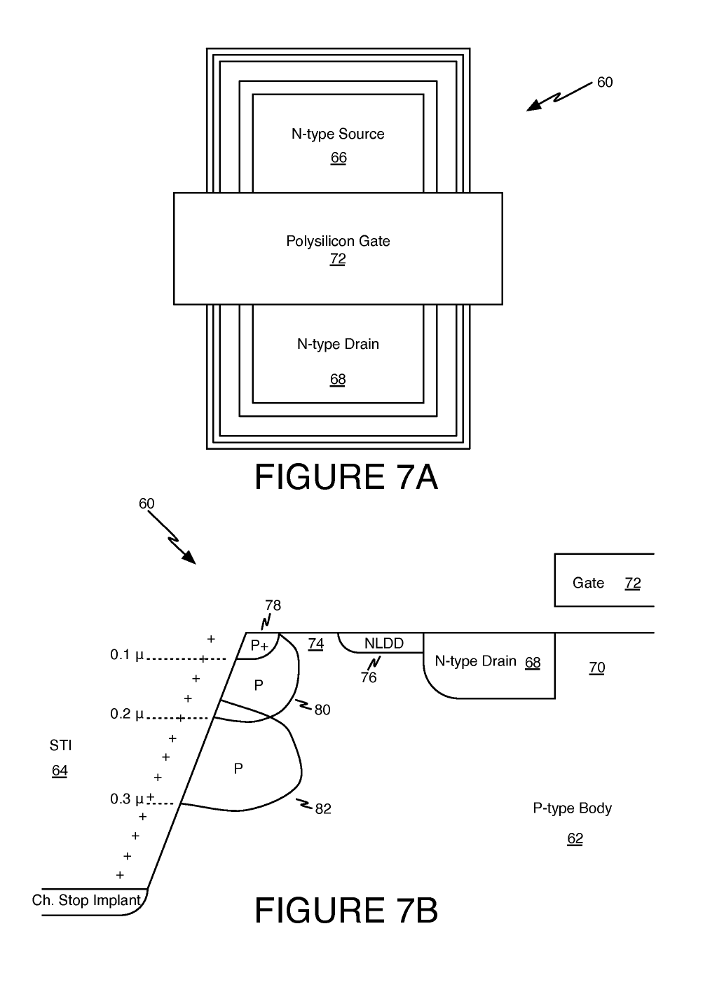

Referring now to FIGS. 7A and 7B, another embodiment of the present invention is shown. FIG. 7A is a top view of the structure of a transistor 60 fabricated according to this aspect of the present invention. FIG. 7B is a cross-sectional view of the drain side of transistor 40 taken in a direction parallel to the channel.

The NMOS transistor 60 resides in a p-well 62, which may be a high-voltage triple well, including a body p-well in a deep-n-well in a p-substrate. Transistor 60 is isolated by STI region 64 that surrounds the transistor. Source 66 and drain 68 define a channel region 70 disposed under a polysilicon gate 72. A typical doping level for sources and drains is from about 1×10¹⁹ atoms/cm³ to about 1×10¹⁹ atoms/cm³.

The lateral diode in transistor 60 is formed by pulling the N+ source and drain implant back from the diffusion edge at STI region 64, leaving only the body p-type well 62 (or substrate) doping. The source/drain junction is then graded by introducing a region 76 of lighter n-type lightly-doped-drain (NLDD) implant extending beyond the N+ source/drain regions. In an embodiment where the N+ source/drain diffusions have a doping level of about 1E19-1E20 atoms/cm³, the NLDD implant can have a level of about 1E18 atoms/cm³. The perimeter of the diffusion is then implanted with a P+ implant 78 to create a very high parasitic threshold voltage for ionizing radiation immunity. Typical doping levels for p-type implant 78 are about 1×10¹⁹ to about 1×10²⁰ atoms/cm³. The P+ to p-well doping profile is graded by introducing a lighter p-type implant 80 encompassing the P+ region. Typical doping levels for p-type implant 80 are about 1×10¹⁸ atoms/cm³. Finally, another p-type implant 82, deeper than implant 80, is added at the diffusion edge to increase the sidewall V_{T} and prevent punch-through to the transistor sidewall under high junction stresses. Typical doping levels for p-type implant 82 are about 1×10¹⁸ atoms/cm³. All of these implants may be made using a species such as boron.

In the embodiment of the invention illustrated in FIGS. 7A and 7B, the p-type isolation is present only on the drain edges of the transistor. This allows for a reduction in the “x”-pitch of the transistor layout without any degradation of either the TID robustness or the junction breakdown.

The present invention provides a significant total footprint reduction as compared to existing radiation-hardened layouts. It offers smaller source and drain junctions, reducing parasitic leakage and capacitance for better performance. The transistors also readily scalable in channel width and length, which is critical for efficient circuit design. This invention is implemented using a standard commercially available processes without need for modification, achieving radiation hardness solely via device layout.

Persons of ordinary skill in the art will appreciate that the concepts of the present invention may be used to fabricate multiple transistors sharing a common central diffusion (e.g., a source region) with a pair of opposed drains extending in opposite directions from the central diffusion.

The transistors of the present invention are easily fabricated using standard CMOS process modules. First, the trenches are formed. The radiation-hardening p-type implant to the trench walls is then performed. Next, polysilicon for the gates is deposited. The gates are then defined. A p-channel mask is applied for the p-type isolation rings. Then, if the transistors are to be high-voltage transistors an LDD implant is performed. Then an LDD mask is applied and the source/drain implants are performed.

In this specification, the relative term “high-voltage” or “HV” is used with respect to transistors. Persons of ordinary skill in the art will appreciate that these terms are interchangeable. Such skilled persons will also appreciate that a high-voltage transistor is a transistor able to withstand more than 5V, usually higher than 10V.

While embodiments and applications of this invention have been shown and described, it would be apparent to those skilled in the art that many more modifications than mentioned above are possible without departing from the inventive concepts herein. The invention, therefore, is not to be restricted except in the spirit of the appended claims.

What is claimed is:

1. A radiation-hardened transistor, comprising:
a p-type body;
an active region within the p-type body having a perimeter defined by a shallow-trench isolation region filled with a dielectric material;
spaced-apart source and drain regions disposed in the active region, forming a channel therebetween;
a polysilicon gate disposed above, aligned with, and insulated from the channel region; and
a p-type isolation ring in the p-type body separating outer edges of at least one of the source and drain regions from the perimeter of the active region.

2. The transistor of claim 1 wherein the p-type body is a p-type body well disposed in triple-well HV well structure including a p-type substrate, a deep n-type well disposed in the p-type substrate, the p-type body well disposed in the deep n-well.

3. The transistor of claim 1 wherein the p-type isolation ring separates outer edges of both the source and drain regions from the perimeter of the active region.

4. The transistor of claim 1, wherein the p-type isolation ring includes a first portion adjacent to the outer edges of at least one of the source and drain regions from the perimeter of the active region and a second portion outside of the first portion extending to the perimeter of the active region.

5. The transistor of claim 1 further including by a lightly-doped n-type region surrounding the outer edges of at least one of the source and drain regions and wherein the p-type isolation ring is disposed outside of the lightly-doped n-type region.

6. The transistor of claim 4, wherein the first portion of the p-type isolation ring comprises a portion of the p-type substrate.

7. The transistor of claim 1, further including lightly-doped regions at outer peripheries of the source and drain regions.

8. The transistor of claim 7, wherein the second portion of the p-type isolation region includes a first p-type implant at the surface of the active region.

9. The transistor of claim 8, wherein the second portion of the p-type isolation region further includes a second p-type implant disposed below the first p-type implant.

10. The transistor of claim 9, wherein the second p-type implant is lighter than the first p-type implant.

11. The transistor of claim 9, wherein the second portion of the p-type isolation region further includes a third p-type implant disposed below the second p-type implant.

12. The transistor of claim 11, wherein the second p-type implant is lighter than the first p-type implant, and the third p-type implant is lighter than the second p-type implant.
